(19) United States
(12) Patent Application Publication
(10) Pub. No.: US 2025/0311352 A1
(43) Pub. Date: Oct. 2, 2025

(54) SEMICONDUCTOR PLACEHOLDER, SOURCE/DRAIN, AND CONTACT

(71) Applicant: INTERNATIONAL BUSINESS MACHINES CORPORATION, ARMONK, NY (US)

(72) Inventors: Fabio Carta, Pleasantville, NY (US); Tao Li, Slingerlands, NY (US); Shogo Mochizuki, Mechanicville, NY (US); Ruilong Xie, Niskayuna, NY (US); Kisik Choi, Watervliet, NY (US)

(21) Appl. No.: 18/617,158

(22) Filed: Mar. 26, 2024

(51) Int. Cl. H01L 29/66; H01L 29/06; H01L 29/08; H01L 29/417

(52) U.S. Cl. CPC H10D 64/017; H10D 62/121; H10D 62/151; H10D 64/251

(57) ABSTRACT

A semiconductor structure extends laterally with a first interconnect on one side and a second interconnect on an opposing side separated from the first interconnect by a longitudinal thickness of an insulating member that extends laterally along the first interconnect and the second interconnect. The semiconductor structure includes a first source/drain (S/D) positioned in the insulating member between the first interconnect and the second interconnect, and a first contact electrically connected to the first S/D and to the first interconnect. The first S/D extends along a first two opposing sides of the first contact.

### BACKGROUND

The present disclosure relates to semiconductor devices, and more specifically, to placeholders, source/drains, and their electrical contacts in an integrated circuit.

Field-effect transistors (“FETs”) use an electric field effect to control current flow within a semiconductor device. Specifically, FETs may use the electric charge of their gates to affect and control the current flow through a channel. The performance of FETs can be affected by the quality of their electrical connections, for example, due to needless electrical resistance in the flowpath. In addition, during the manufacturing of FETs, placeholders can be used. These placeholders are parts of an intermediary version of the semiconductor structure, and they will be replaced by their corresponding final components at one or more manufacturing operations.

### SUMMARY

In one embodiment of the present disclosure, a semiconductor structure extends laterally with a first interconnect on one side and a second interconnect on an opposing side separated from the first interconnect by a longitudinal thickness of an insulating member that extends laterally along the first interconnect and the second interconnect. The semiconductor structure includes a first source/drain (S/D) positioned in the insulating member between the first interconnect and the second interconnect, and a first contact electrically connected to the first S/D and to the first interconnect. The first S/D extends along a first two opposing sides of the first contact.

In one embodiment of the present disclosure, a semiconductor structure extends laterally with a first interconnect on one side and a second interconnect on an opposing side separated from the first interconnect by a longitudinal thickness of an insulating member that extends laterally along the first interconnect and the second interconnect. The semiconductor structure includes a first S/D positioned in the insulating member between the first interconnect and the second interconnect, a first contact electrically connected to the first S/D and to the first interconnect, and a placeholder positioned between the first S/D and the second interconnect. The first source/drain extends along a first two opposing sides of the placeholder.

In one embodiment of the present disclosure, a method of manufacturing a semiconductor structure includes providing an intermediary semiconductor structure including a first insulator and a substrate in direct contact with the first insulator. The method also includes forming a first placeholder in a first pore in the substrate, removing portions of the first placeholder so that the first placeholder has an inverted T-shape, forming a first S/D on the first placeholder, forming a second insulator on the first S/D, removing the substrate to expose the first placeholder, forming a third insulator on the placeholder, removing the first placeholder to expose the first S/D, and forming a first contact on the first S/D in a second pore in the third insulator.

### BRIEF DESCRIPTION OF THE DRAWINGS

FIG. 1A is a schematic top view of a semiconductor structure, in accordance with embodiments of the present disclosure.

FIGS. 1B, 1C, and 1D are cross-section views of the semiconductor structure, in accordance with embodiments of the present disclosure.

FIG. 2 is a flowchart of a method of manufacturing the semiconductor structure of FIG. 1, in accordance with an embodiment of the present disclosure.

FIGS. 3A, 3B, 3C, 3D, 3E, 3F, 3G, 3H, 3I, 3J, and 3K are a series of cross-section views of stages in a manufacture of the semiconductor structure according to the method of FIG. 2, in accordance with an embodiment of the present disclosure.

### DETAILED DESCRIPTION

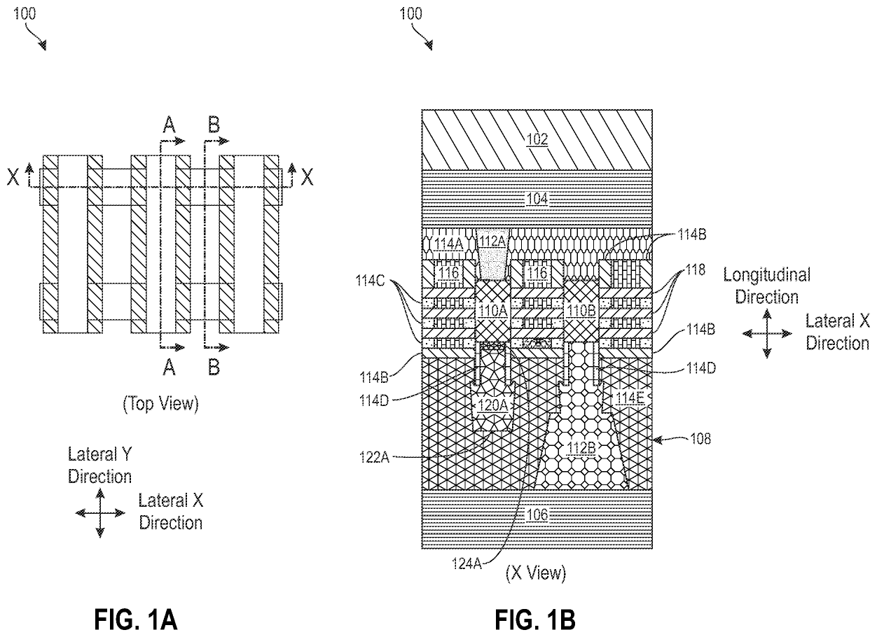

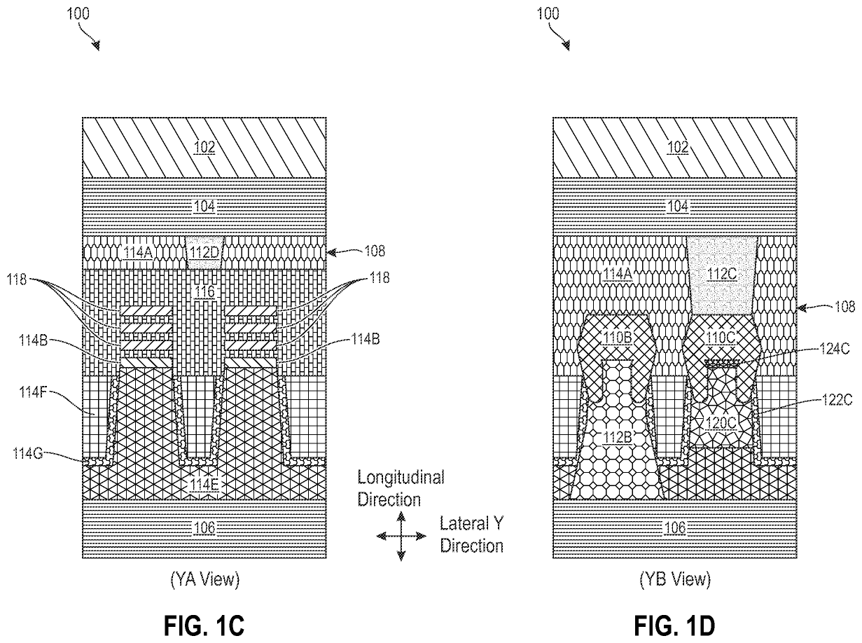

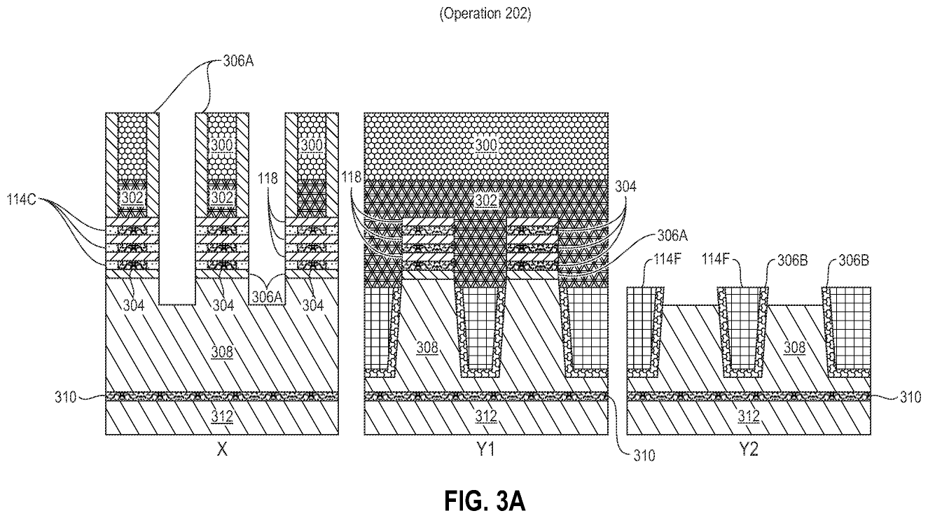

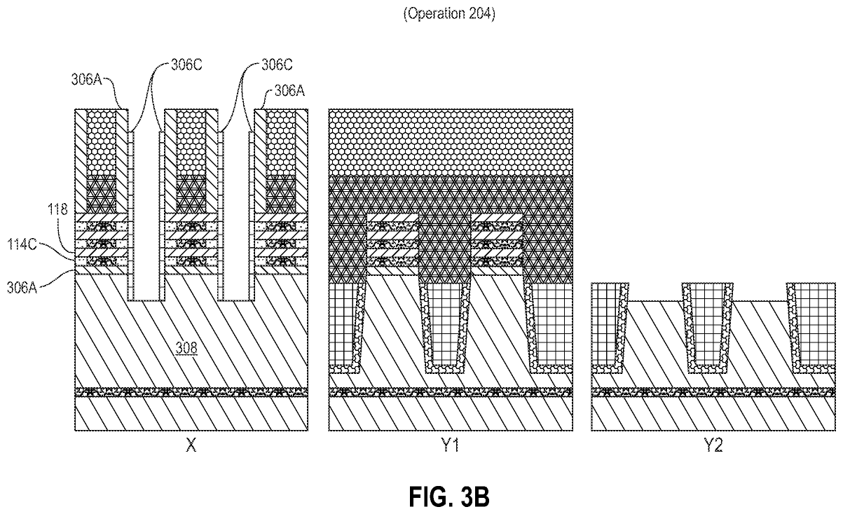

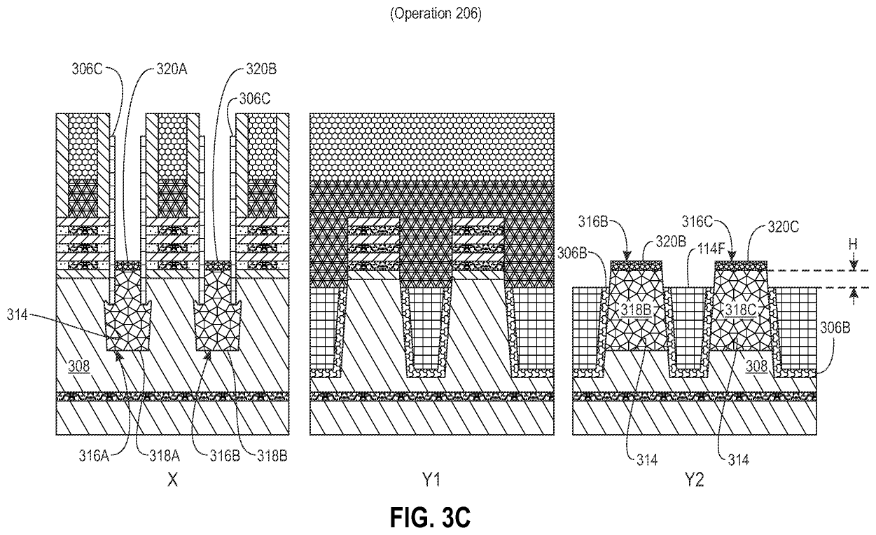

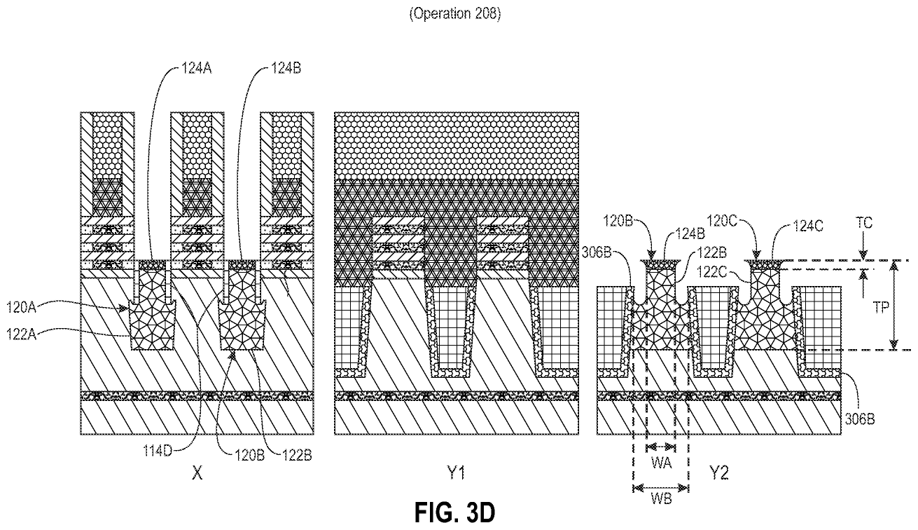

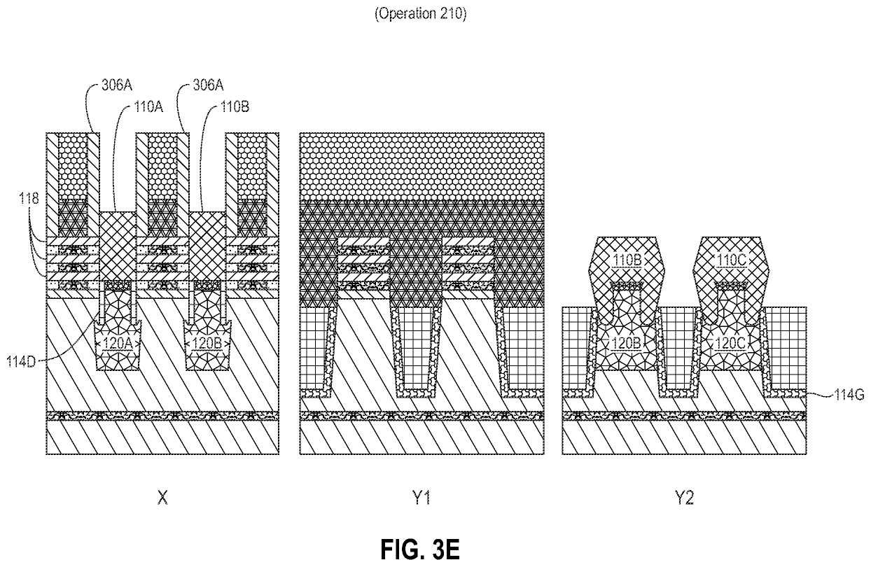

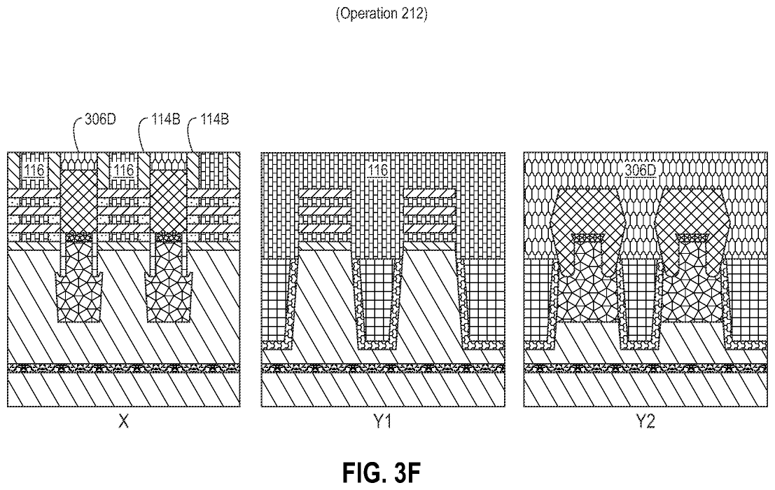

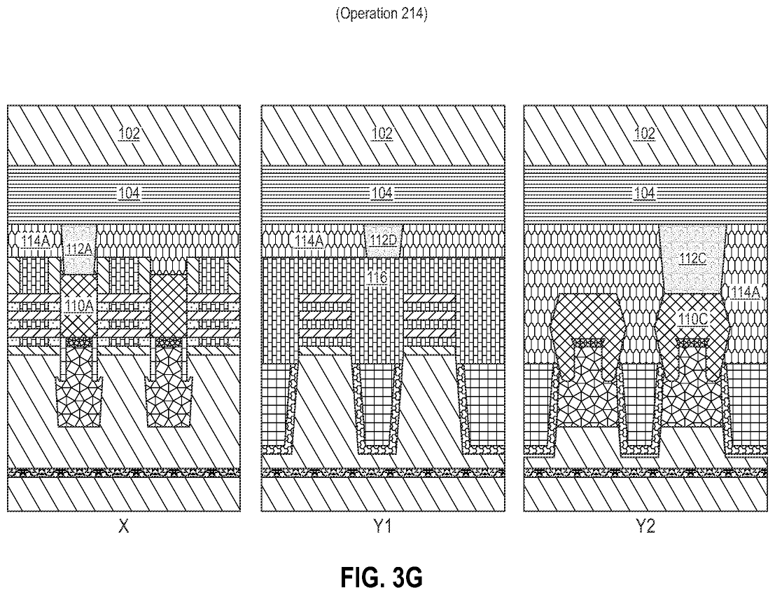

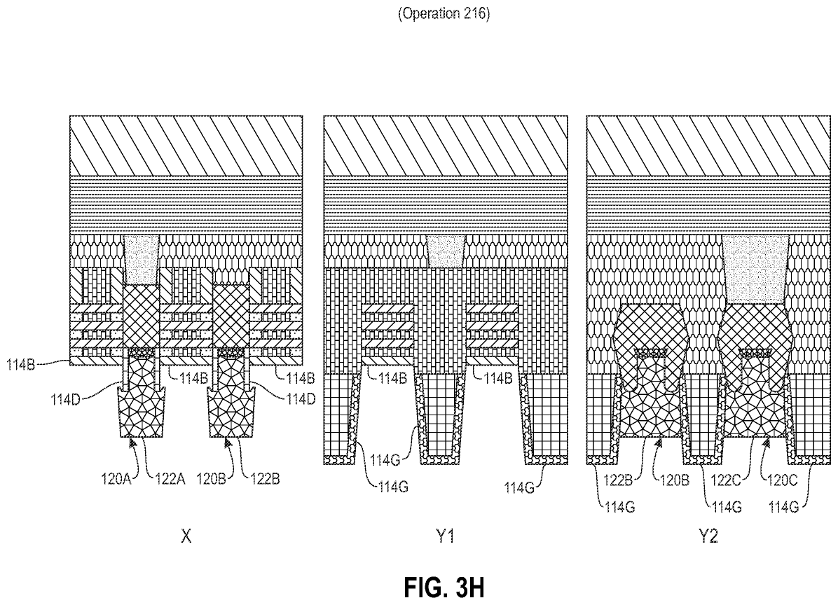

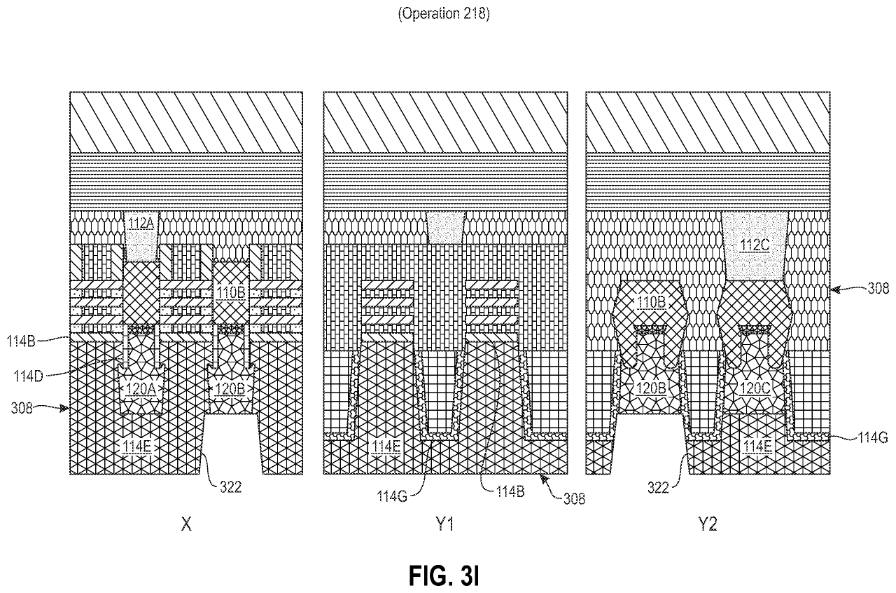

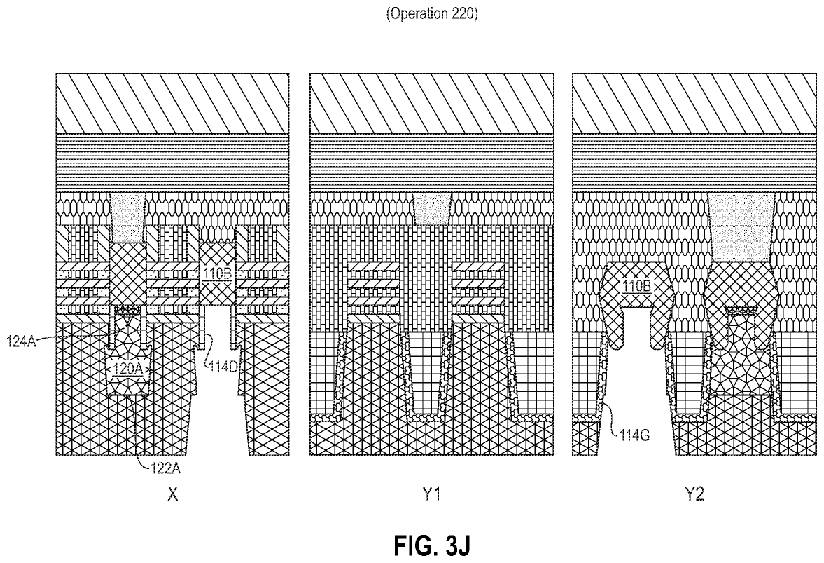

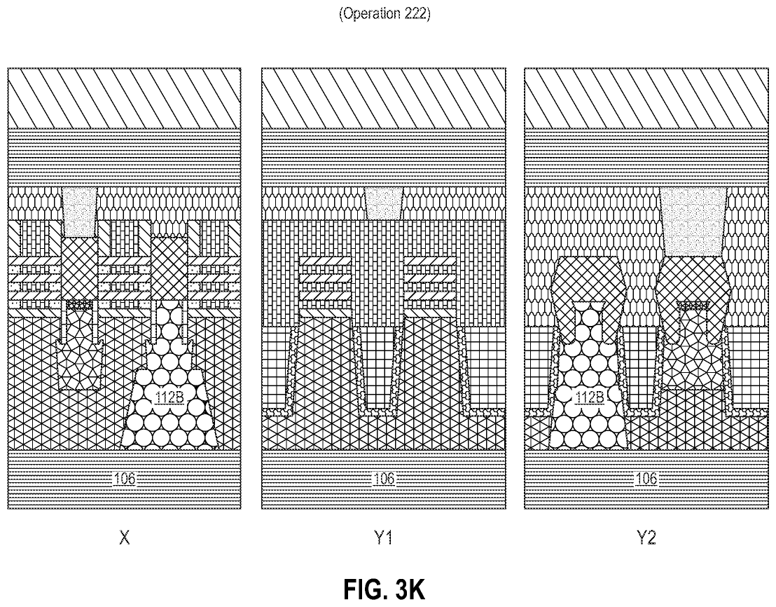

FIG. 1A is a schematic top view of semiconductor structure 100, and FIGS. 1B, 1C, and 1D are cross-section views of semiconductor structure 100. FIG. 1B is an “X” view, the orientation and location of which is indicated by line X-X in FIG. 1A. FIG. 1C is a “YA” view, the orientation and location of which is indicated by line A-A in FIG. 1A. FIG. 1D is a “YB” view, the orientation and location of which is indicated by line B-B in FIG. 1A. The schematic top view of FIG. 1A provides a frame of reference for FIGS. 3A-3K as well. It should be noted that there are components and/or features in the Figures that occur in multiple locations, but, for the sake of simplicity, only some (or one) of them may be labeled in a given Figure. However, the Figures are drawn such that a person having ordinary skill in the art would understand where the other occurrences are.

In the illustrated embodiment, semiconductor structure 100 includes wafer 102, top interconnect 104, bottom interconnect 106, and insulating member 108. The space between top interconnect 104 and bottom interconnect 106 can be considered the device region because many electronic components reside in insulating member 108. For example, top interconnect 104, bottom interconnect 106, source/drain epitaxials (“S/Ds”) 110A-110C (collectively “S/Ds 110”), and contacts 112A-112D (collectively “contacts 112”) are selectively electrically connected together within insulating member 108 and are selectively electrically insulated from one another by insulating member 108 depending on the design of semiconductor structure 100. Insulating member 108 can be comprised of different electrically insulating structures, such as, for example, insulators 114A-114G (collectively “insulators 114”), which can be formed at various times during the manufacture of semiconductor structure 100. Each insulator 114 of insulating member 108 can be comprised of a medium dielectric constant material (a.k.a. mid-κ), such as, for example, silicon nitride (SiN), silicon dioxide (SiO₂), silicon nitride carbide (SiNC), tetraethyl orthosilicate (TEOS), silicon oxycarbide (SiCOₓ), silicon oxycarbonitride (SiCNO), or siliconboron carbonitride (SiBCN), or a mixture of one or more of the aforementioned materials. Insulators 114 can be comprised of the same material or different materials, and a material can appear in multiple insulators 114. While one embodiment of insulating member 108 is shown in FIGS. 1B-1D, other configurations and combinations of insulators are possible.

In the illustrated embodiment, semiconductor structure 100 further includes gates 116 and nanosheets 118. Gates 116 and S/Ds 110 are separated from each other by insulators 114B and 114C and nanosheets 118. Thus, semiconductor structure 100 includes nanosheet transistors (not labeled for the sake of simplicity). For semiconductor structure 100 to function as intended, electrical connections are made within insulating member 108. These connections can be further connected to top interconnect 104 and/or bottom interconnect 106. For example, the top sides of contacts 112A, 112C, and 112D are in direct contact with the bottom side of top interconnect 104, and the bottom side of contact 112B is in direct contact with the top side of bottom interconnect 106. In turn, the bottom sides of contacts 112A, 112C, and 112D are in direct contact with the top sides of S/Ds 110A and 110C and gate 116, respectively, and the top side of contact 112B is in direct contact with the bottom side of S/D 110B. The signal transmission components (e.g., contacts 112) are comprised of an electrically conductive material, such as metal (e.g., titanium nitride (TiN), cobalt (Co), ruthenium (Ru), molybdenum (Mo), or tungsten (W)). The signal transmission components can be comprised of the same material or different materials, and a material can appear in multiple components.

In the illustrated embodiment, the interfaces between S/D 110A and contact 112A and between S/D 110C and contact 112C are flat (i.e., they only extend in the lateral plane). However, the interface between S/D 110B and contact 112B is more complex. This is because the bottom end of S/D 110B has an inverted U-shape, and the top end of contact 112B has a corresponding inverted T-shape. Thus, two opposing sides of the bottom of S/D 110B (i.e., the sides that are separated in the lateral Y direction in FIG. 1D) extend longitudinally along the corresponding two opposing sides of the top of contact 112B (i.e., the sides that are separated in the lateral Y direction in FIG. 1D). However, the other two opposing sides of contact 112B (i.e., the sides that are separated in the lateral X direction in FIG. 1B) extend longitudinally along insulator 114D.

In the illustrated embodiment, semiconductor structure 100 also includes placeholders 120A and 120C (collectively, “placeholders 120”). Placeholders 120 are positioned beneath S/Ds 110 that are connected to top interconnect 104 and not to bottom interconnect 106 (i.e., S/Ds 110A and 110C). Placeholders 120 comprise a relatively large body 122 (e.g., bodies 122A and 122C) on the bottom with a relatively small cap 124 (e.g., caps 124A and 124C) on top of body 122. In some embodiments, the longitudinal thickness TC of cap 124 is about 15 to 35% of the longitudinal thickness TP of placeholder 120. In some embodiments, the longitudinal thickness TC of cap 124 is about 25% of the longitudinal thickness TP of placeholder 120. Note that thicknesses TC and TP are shown in FIG. 3D for the sake of clarity.

In the illustrated embodiment, placeholders 120 are epitaxially grown components that comprise silicon (Si). In some embodiments, the germanium (Ge) content (GC) of bodies 122 is higher than the GC of caps 124, and the GC of caps 124 is higher than the GC of S/Ds 110 (at least, higher than the corresponding S/Ds 110 to placeholders 120). In some embodiments, the GC of bodies 122 is higher than 50%, the GC of caps 124 is less than 30%, and the GC of S/Ds 110 is less than 10%. In some embodiments, the GC of bodies 122 is about 60%, the GC of caps 124 is about 25%, and the GC of S/Ds 110 is about 0% (since S/Ds 110 are 100% Si). It should be noted that the term “about” signifies a variance of +5% points.

The components and configuration of semiconductor structure 100 allow for increased contact area between S/Ds 110 and contacts 112 that are connected to bottom interconnect 106 (e.g., S/D 110B and contact 112B). The increased contact area decreases electrical resistance at the interface between the aforementioned S/Ds 110 and contacts 112, which increases the performance of semiconductor structure 100. In addition, having contacts 112 that connect to top interconnect 104 or bottom interconnect 106 increases freedom for routing signal transmission lines that would otherwise be restricted if all of the power connections went to only one of the interconnects 104 and 106.

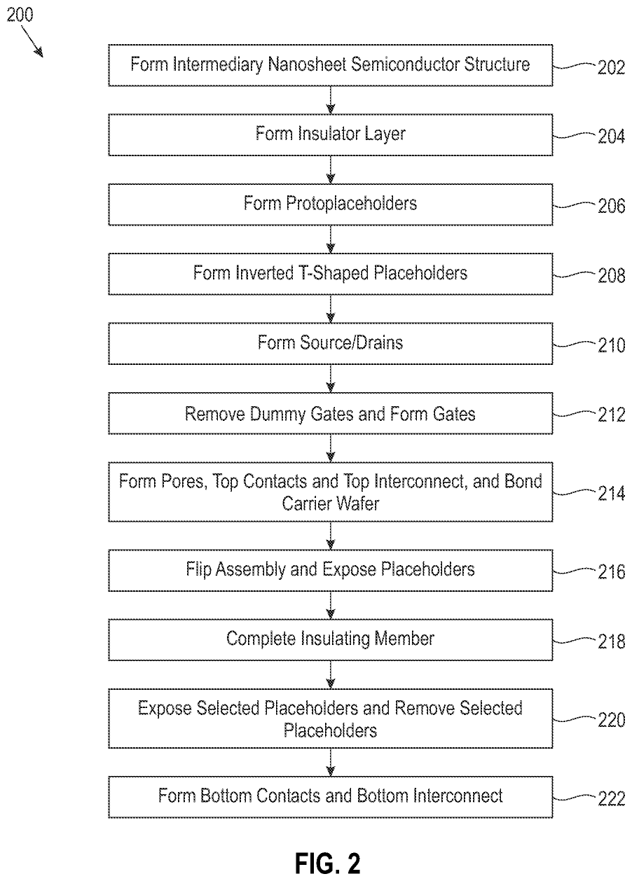

FIG. 2 is a flowchart of method 200 of manufacturing semiconductor structure 100.

FIGS. 3A-3K are a series of cross-section views of stages in a manufacture of the semiconductor structure according to method 200. The results of each operation in method 200 are illustrated in a respective one of FIGS. 3A-3K, so FIGS. 2 and 3A-3K will be discussed in conjunction with one another. In addition, during this discussion, references may be made to features of semiconductor structure 100 (shown in FIGS. 1A-1D), however, some features may be omitted for the sake of simplicity.

In the illustrated embodiment, method 200 begins at operation 202 wherein an intermediary nanosheet semiconductor structure is partially formed. In particular, as shown in FIG. 3A, insulators 114C and 114F, nanosheets 118, gate mask 300, dummy gates 302, gate placeholders 304, insulator layers 306A and 306B, bottom substrate 308, etch stop 310, and bottom wafer 312 are formed.

At operation 204, insulator layer 306C is formed on insulator 114C, nanosheets 118, insulator layer 306A, and bottom substrate 308, as shown in FIG. 3B.

At operation 206, pores 314 are formed in bottom substrate 308. As shown in FIG. 3C, protoplaceholders 316A-316C (collectively “protoplaceholders 316”) are formed in pores 314 that are in bottom substrate 308, and protoplaceholders 316 are in contact with bottom substrate 308 and insulator layers 306C and 306B. Each protoplaceholder 316 comprises protobody 318 (e.g., protobodies 318A-318C) and protocap 320 (e.g., protocaps 320A-320C). In some embodiments, the tops of protobodies 318 are between about 1 nanometer (nm) to 10 nm above the top insulator 114F (labeled in FIG. 3A), as denoted by longitudinal height H. Protoplaceholders 316 can be formed underneath every position where there will be an S/D 110, regardless of whether an S/D 110 will be connected to top interconnect 104 or bottom interconnect 106. This can be known as a “placeholder everywhere” approach. In contrast, in some embodiments, protoplaccholders 316 are only formed underneath positions where the S/D 110 will be connected to bottom interconnect 106 (e.g., S/D 110B, shown in FIG. 1D). In addition, the recesses for protoplaceholders 316 can be dug in the same operation as the recesses for S/Ds 110, so protoplaceholders 316 can be self-aligned with their respective S/Ds 110.

In the illustrated embodiment, at operation 208, portions of insulator layer 306C and protoplaceholders 316 are removed, which exposes portions of insulator layer 306B and completes insulator 114D and placeholders 120. In some embodiments, operation 208 can be a wet etching process that selectively affects protobodies 318 more than it affects protocaps 320 due to the difference in GC therebetween. Because protocaps 320 are less affected by the material removal during operation 208, the tops of protobodies 318 are protected from being removed. Instead, material is removed from the two opposite upper sides of protobodies 318 to form bodies 122. At the same time, some portions of protocaps 320 can also be removed during operation 208 to complete caps 124. As shown in FIG. 3D, the result is that the width (after) WA of the upper ends of bodies 122 is about half of the width (before) WB of the upper ends of protobodies 318 (which is the about the same as the width of the bottom end of bodies 122C). The difference between WB and WA can be affected by the longitudinal thickness of protocaps 320. A person having ordinary skill in the art can understand that very thin protocaps 320 could be completely removed during operation 208, which could result in excessive removal of material from protobodies 318. Conversely, very thick protocaps 320 could result in insufficient removal of material from protobodies 318. Either situation could result in less favorable geometry at the interfaces of some of S/Ds 110 and contacts 112 (as shown in FIG. 1D) such that there is a reduced benefit due to a smaller decrease in electrical resistance therethrough.

In the illustrated embodiment, at operation 210, S/Ds 110 are formed on insulators 114D and 114G, nanosheets 118, and placeholders 120, respectively. As shown in FIG. 3E, insulator 114G has been completed.

At operation 212, gate mask 300, dummy gates 302, and gate placeholders 304 (shown in FIG. 3A) are removed, and portions of insulator layers 306A are removed to complete insulator 114B. As shown in FIG. 3F, gates 116 and insulator layer 306D are formed.

At operation 214, pores are formed in insulator layer 306D to complete insulator 114A. As shown in FIG. 3G, these pores are filled by contacts 112A, 112C, and 112D for S/Ds 110A and 110C and gates 116, respectively. In addition, top interconnect 104 is formed on contacts 112A, 112C, and 112D and on insulator 114A, and carrier wafer 102 is bonded to top interconnect 104.

In the illustrated embodiment, at operation 216, the partially-formed assembly that has been made so far is flipped to provide access to its bottom side. (However, the orientation has not changed from FIG. 3G to FIG. 3H for visual continuity.) As shown in FIG. 3H, bottom substrate 308, etch stop 310, and bottom wafer 312 are removed to expose insulators 114B, 114D, and 114G as well as placeholders 120. In some embodiments, bottom substrate 308 is made of an Si material with 0% GC. In such embodiments, selectively removing bottom substrate 308 without damaging placeholders 120 can be achieved due to the higher GC of placeholders 120 (specifically, that of bodies 122).

At operation 218, insulator 114E is formed on insulators 114B, 114D, and 114G and placeholders 120 to complete insulating member 108. As shown in FIG. 3I, insulator 114 includes pore 322 so that placeholder 120B is purposefully exposed, since the bottom of S/D 110B will be connected to contact 112B. However, placeholders 120A and 120C are covered by insulator 114 since they are already connected to contacts 112A and 112C, respectively.

In the illustrated embodiment, at operation 220, placeholder 120B is selectively removed which exposes S/D 110B, insulator 114D, and some of insulator 114G, as shown in FIG. 3J. In some embodiments, S/D 110B is made of an Si material with low or no percent GC. In such embodiments, selectively removing placeholder 120B without damaging S/D 110B can be achieved due to the higher GCs of placeholder 120B (specifically, that of body 122B and cap 124B).

At operation 222, contact 112B is formed on S/D 110B and insulators 114D, 114E, and 114G. As shown in FIG. 3K, bottom interconnect 106 is formed on contact 112B and insulator 114E to complete semiconductor structure 100.

The features of method 200 allow for placeholders 120 to be narrowed or rebated at the top ends as to have an inverted T-shape such that the bottom ends of S/Ds 110 have a corresponding inverted U-shape. Where desired, placeholders 120 can be removed and contacts 112 can be formed to connect the selected S/Ds 110 to bottom interconnect 106. In doing so, the electrical resistance at the interface of the selected S/D 110 and its respective contact 112 is reduced compared to a purely planar interface therebetween. In addition, since bodies 122 and caps 124 have higher GC percentages than either S/Ds 110 or bottom substrate 308, there is material removal (e.g., etching) selectivity between these components.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layers “C” and “D”) are between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus. In addition, any numerical ranges included herein are inclusive of their boundaries unless explicitly stated otherwise.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process operations described herein can be incorporated into a more comprehensive procedure or process having additional operations or functionality not described in detail herein. In particular, various operations in the manufacture of semiconductor devices and semiconductor-based ICs are well known and so, in the interest of brevity, many conventional operations will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography.

Deposition can be any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Another deposition technology is plasma enhanced chemical vapor deposition (PECVD), which is a process which uses the energy within the plasma to induce reactions at the wafer surface that would otherwise require higher temperatures associated with conventional CVD. Energetic ion bombardment during PECVD deposition can also improve the film's electrical and mechanical properties.

Removal/etching can be any process that removes material from the wafer. Examples include etch processes (either wet or dry), chemical mechanical planarization (CMP), and the like. One example of a removal process is ion beam etching (IBE). In general, IBE (or milling) refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (RIE). In general, RIE uses chemically reactive plasma to remove material deposited on wafers. With RIE the plasma is generated under low pressure (vacuum) by an electromagnetic field. High-energy ions from the RIE plasma attack the wafer surface and react with it to remove material.

Semiconductor doping can be the modification of electrical properties by doping, for example, transistor sources and drains, generally by diffusion and/or by ion implantation. These doping processes are followed by furnace annealing or by rapid thermal annealing (“RTA”). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Semiconductor lithography can be the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer operations are repeated multiple times. Each pattern being printed on the wafer is aligned to the previously formed patterns and gradually the conductors, insulators and selectively doped regions are built up to form the final device.

The following are non-exclusive descriptions of some example embodiments of the present disclosure.

A semiconductor structure, according to an example embodiment of this disclosure, among other possible things, extends laterally with a first interconnect on one side and a second interconnect on an opposing side separated from the first interconnect by a longitudinal thickness of an insulating member that extends laterally along the first interconnect and the second interconnect. The semiconductor structure includes: a first S/D positioned in the insulating member between the first interconnect and the second interconnect; and a first contact electrically connected to the first S/D and to the first interconnect. The first S/D extends along a first two opposing sides of the first contact. Such an embodiment can provide the technical effect and/or advantage of increasing the contact area between the first S/D and the first contact, which decreases electrical resistance at the interface there between. This increases the performance of the semiconductor structure.

The semiconductor structure of the preceding paragraph can optionally include, additionally and/or alternatively, any one or more of the following features, configurations, and/or additional components.

In a further embodiment of the foregoing semiconductor structure, a second S/D is positioned in the insulating member adjacent to the first S/D; a second contact is electrically connected to the second S/D and to the second interconnect; and a placeholder is positioned between the second S/D and the first interconnect. The second source/drain extends along a first two opposing sides of the placeholder. Such an embodiment can provide the technical effect and/or advantage of allowing a “placeholder everywhere” approach to the manufacturing of the semiconductor structure.

In a further embodiment of any of the foregoing semiconductor structures, the placeholder includes a body comprised of a first material; and a cap comprised of a second material that is different from the first material. Such an embodiment can provide the technical effect and/or advantage of allowing the cap and the body to be affected by a material removal operation differently, which can result in the placeholder having an inverted T-shape.

In a further embodiment of any of the foregoing semiconductor structures, the first material comprises a higher germanium content than the second material. Such an embodiment can provide the technical effect and/or advantage of having material removal selectivity between the body and a substrate.

In a further embodiment of any of the foregoing semiconductor structures, the first material includes a first germanium content greater than 50%; and the second material includes a second germanium content less than 30%. Such an embodiment can provide the technical effect and/or advantage of allowing the cap and the body to be affected by a material removal operation differently, which can result in the placeholder having an inverted T-shape.

In a further embodiment of any of the foregoing semiconductor structures, a germanium content of the second S/D is less than 5%. Such an embodiment can provide the technical effect and/or advantage of having material removal selectivity between the placeholder and the second S/D.

In a further embodiment of any of the foregoing semiconductor structures, a longitudinal thickness of the cap is about 25% of a longitudinal thickness of the placeholder. Such an embodiment can provide the technical effect and/or advantage of controlling the amount of material removal from the body during manufacturing.

In a further embodiment of any of the foregoing semiconductor structures, a first width of the body where the body contacts the cap is about half of a second width of the body where the body contacts the first contact. Such an embodiment can provide the technical effect and/or advantage of increasing the contact area between the first S/D and the first contact while still providing sufficient cross-sectional areas for current flow in the first S/D and the first contact.

In a further embodiment of any of the foregoing semiconductor structures, an insulative liner extends along a second two opposing sides of the first contact that are different from the first two opposing sides of the first contact. Such an embodiment can provide the technical effect and/or advantage of controlling the size of the pores for the placeholders.

A semiconductor structure, according to an example embodiment of this disclosure, among other possible things, extends laterally with a first interconnect on one side and a second interconnect on an opposing side separated from the first interconnect by a longitudinal thickness of an insulating member that extends laterally along the first interconnect and the second interconnect. The semiconductor structure includes: a first S/D positioned in the insulating member between the first interconnect and the second interconnect; a first contact electrically connected to the first S/D and to the first interconnect; and a placeholder positioned between the first S/D and the second interconnect. The first source/drain extends along a first two opposing sides of the placeholder. Such an embodiment can provide the technical effect and/or advantage of allowing a “placeholder everywhere” approach to the manufacturing of the semiconductor structure.

The semiconductor structure of the preceding paragraph can optionally include, additionally and/or alternatively, any one or more of the following features, configurations, and/or additional components.

In a further embodiment of the foregoing semiconductor structure, the placeholder includes: a body including a first material; and a cap including a second material that is different from the first material. Such an embodiment can provide the technical effect and/or advantage of controlling the amount of material removal from the body.

In a further embodiment of any of the foregoing semiconductor structures, the first material includes a higher germanium content than the second material. Such an embodiment can provide the technical effect and/or advantage of having material removal selectivity between the body and a substrate.

In a further embodiment of any of the foregoing semiconductor structures, the first material includes a first germanium content greater than 50%; and the second material includes a second germanium content less than 30%. Such an embodiment can provide the technical effect and/or advantage of allowing the cap and the body to be affected by a material removal operation differently, which can result in the placeholder having an inverted T-shape.

In a further embodiment of any of the foregoing semiconductor structures, a germanium content of the first S/D is less than 5%. Such an embodiment can provide the technical effect and/or advantage of having material removal selectivity between the placeholder and the second S/D.

In a further embodiment of any of the foregoing semiconductor structures, a longitudinal thickness of the cap is about 25% of a longitudinal thickness of the placeholder. Such an embodiment can provide the technical effect and/or advantage of controlling the amount of material removal from the body during manufacturing.

In a further embodiment of any of the foregoing semiconductor structures, a first width of the body where the body contacts the cap is about half of a second width of the body at an opposite end of the body. Such an embodiment can provide the technical effect and/or advantage of increasing the contact area between the first S/D and the first contact while still providing sufficient cross-sectional areas for current flow in the first S/D and the first contact.

In a further embodiment of any of the foregoing semiconductor structures, an insulative liner extends along a second two opposing sides of the placeholder that are different from the first two opposing sides of the placeholder. Such an embodiment can provide the technical effect and/or advantage of controlling the size of the pores for the placeholders.

A method of manufacturing a semiconductor structure, according to an example embodiment of this disclosure, among other possible things, includes: providing an intermediary semiconductor structure including: a first insulator; and a substrate in direct contact with the first insulator. The method also includes: forming a first placeholder in a first pore in the substrate; removing portions of the first placeholder so that the first placeholder has an inverted T-shape; forming a first S/D on the first placeholder; forming a second insulator on the first S/D; removing the substrate to expose the first placeholder; forming a third insulator on the placeholder; removing the first placeholder to expose the first S/D; and forming a first contact on the first S/D in a second pore in the third insulator. Such an embodiment can provide the technical effect and/or advantage of increasing the contact area between the first S/D and the first contact, which decreases electrical resistance at the interface there between. This increases the performance of the semiconductor structure.

The semiconductor method of the preceding paragraph can optionally include, additionally and/or alternatively, any one or more of the following features, configurations, and/or additional components.

In a further embodiment of the foregoing methods, forming the first placeholder includes: forming a body with a first germanium content; and forming a cap on the body with a second germanium content. The first germanium content is higher than the second germanium content. Such an embodiment can provide the technical effect and/or advantage of having material removal selectivity between the body and a substrate.

In a further embodiment of any of the foregoing methods, the method further includes: forming a second placeholder in a third pore in the substrate; forming a second S/D on the second placeholder; and forming a second contact in a fourth pore in the second insulator. The second placeholder is not removed. Such an embodiment can provide the technical effect and/or advantage of allowing a “placeholder everywhere” approach to the manufacturing of the semiconductor structure.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure that extends laterally with a first interconnect on one side and a second interconnect on an opposing side separated from the first interconnect by a longitudinal thickness of an insulating member that extends laterally along the first interconnect and the second interconnect, the semiconductor structure comprising:
a first source/drain (S/D) positioned in the insulating member between the first interconnect and the second interconnect; and
a first contact electrically connected to the first S/D and to the first interconnect;
wherein the first S/D extends along a first two opposing sides of the first contact.

2. The semiconductor structure of claim 1, further comprising:
a second S/D positioned in the insulating member adjacent to the first S/D;
a second contact electrically connected to the second S/D and to the second interconnect; and
a placeholder positioned between the second S/D and the first interconnect;
wherein the second source/drain extends along a first two opposing sides of the placeholder.

3. The semiconductor structure of claim 2, wherein the placeholder comprises:
a body comprised of a first material; and
a cap comprised of a second material that is different from the first material.

4. The semiconductor structure of claim 3, wherein the first material comprises a higher germanium content than the second material.

5. The semiconductor structure of claim 4, wherein:
the first material comprises a first germanium content greater than 50%; and
the second material comprises a second germanium content less than 30%.

6. The semiconductor structure of claim 4, wherein a germanium content of the second S/D is less than 5%.

7. The semiconductor structure of claim 3, wherein a longitudinal thickness of the cap is about 25% of a longitudinal thickness of the placeholder.

8. The semiconductor structure of claim 3, wherein a first width of the body where the body contacts the cap is about half of a second width of the body where the body contacts the first contact.

9. The semiconductor structure of claim 1, further comprising an insulative liner extending along a second two opposing sides of the first contact that are different from the first two opposing sides of the first contact.

10. A semiconductor structure that extends laterally with a first interconnect on one side and a second interconnect on an opposing side separated from the first interconnect by a longitudinal thickness of an insulating member that extends laterally along the first interconnect and the second interconnect, the semiconductor structure comprising:
a first source/drain (S/D) positioned in the insulating member between the first interconnect and the second interconnect;
a first contact electrically connected to the first S/D and to the first interconnect; and
a placeholder positioned between the first S/D and the second interconnect;
wherein the first source/drain extends along a first two opposing sides of the placeholder.

11. The semiconductor structure of claim 10, wherein the placeholder comprises:
a body comprised of a first material; and
a cap comprised of a second material that is different from the first material.

12. The semiconductor structure of claim 11, wherein the first material comprises a higher germanium content than the second material.

13. The semiconductor structure of claim 12, wherein:
the first material comprises a first germanium content greater than 50%; and
the second material comprises a second germanium content less than 30%.

14. The semiconductor structure of claim 13, wherein a germanium content of the first S/D is less than 5%.

15. The semiconductor structure of claim 11, wherein a longitudinal thickness of the cap is about 25% of a longitudinal thickness of the placeholder.

16. The semiconductor structure of claim 11, wherein a first width of the body where the body contacts the cap is about half of a second width of the body at an opposite end of the body.

17. The semiconductor structure of claim 10, further comprising an insulative liner extending along a second two opposing sides of the placeholder that are different from the first two opposing sides of the placeholder.

18. A method of manufacturing a semiconductor structure comprises:
providing an intermediary semiconductor structure comprising:
a first insulator; and
a substrate in direct contact with the first insulator;
forming a first placeholder in a first pore in the substrate;
removing portions of the first placeholder so that the first placeholder has an inverted T-shape;
forming a first source/drain (S/D) on the first placeholder;
forming a second insulator on the first S/D;
removing the substrate to expose the first placeholder;
forming a third insulator on the placeholder;
removing the first placeholder to expose the first S/D; and
forming a first contact on the first S/D in a second pore in the third insulator.

19. The method of claim 18, wherein forming the first placeholder comprises:
forming a body with a first germanium content; and
forming a cap on the body with a second germanium content;
wherein the first germanium content is higher than the second germanium content.

20. The method of claim 18, further comprising:
forming a second placeholder in a third pore in the substrate;
forming a second S/D on the second placeholder; and
forming a second contact in a fourth pore in the second insulator;
wherein the second placeholder is not removed.
